(19) United States
(12) Patent Application Publication
(10) Pub. No.: US 2008/0032466 A1
(43) Pub. Date: Feb. 7, 2008

(54) Method for Fabricating Semiconductor Device

(75) Inventor: Tae Kyung Oh, Jeju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/608,727

(22) Filed: Dec. 8, 2006

(30) Foreign Application Priority Data
Jul. 24, 2006 (KR) 10-2006-0069210

(51) Int. Cl. H01L 21/84; H01L 21/00

(52) U.S. Cl. 438/149

(57) ABSTRACT

A method for fabricating a semiconductor device includes forming a silicon layer pattern in a Silicon-on-Insulator (“SOI”) semiconductor substrate to define an active region, selectively patterning an insulating film in the SOI semiconductor substrate by using a gate mask to form an under-cut space under the silicon layer pattern, and forming a gate structure including a gate electrode pattern and a gate hard mask layer pattern formed over the gate electrode pattern. The gate electrode pattern surrounds the silicon layer pattern thereby filling up the under-cut space.

### CROSS-REFERENCES TO RELATED APPLICATIONS

The present application claims priority to Korean patent application number 10-2006-0069210, filed on Jul. 24, 2006, which is incorporated by reference in its entirety.

### BACKGROUND OF THE INVENTION

The present invention relates to a memory device. More particularly, the present invention relates to a method for fabricating a semiconductor device having a surrounded channel transistor.

When the channel length of a cell transistor is decreased, the ion concentration of the cell channel structure is generally increased in order to maintain threshold voltage of the cell transistor. Due to the increase in the ion concentration of the cell channel structure, an electric field in the source/drain regions of the cell transistor is enhanced to increase leakage current. This results in the degradation of the refresh characteristics of a DRAM structure. In addition, as the semiconductor device shrinks to smaller sizes, it is difficult to effectively control the short channel effect (“SCE”). Therefore, new structures of the transistor such as a recess gate transistor and a fin channel transistor have been proposed to increase the channel length of the cell transistor.

However, these structures of the semiconductor device are difficult to surround the channel structure of the transistor, which lowers the gate controllability and the performance of the device. Accordingly, it would be desirable to develop a structure of the transistor that improves the gate controllability and performance of the device.

### BRIEF SUMMARY OF THE INVENTION

Embodiments of the present invention are directed to a method for fabricating a semiconductor device having a surrounded channel transistor with a Silicon-on-Insulator (“SOI”) substrate. According to one embodiment of the present invention, the surrounded channel transistor has a surrounded channel structure including an under-cut space and a gate structure that surrounds the surrounded channel structure.

In another embodiment of the present invention, a method for fabricating a semiconductor device comprises forming a silicon layer pattern in a Silicon-on-Insulator (“SOI”) semiconductor substrate to define an active region; selectively patterning an insulating film in the SOI semiconductor substrate by using a gate mask to form an under-cut space under the silicon layer pattern; and forming a gate structure including a gate electrode pattern and a gate hard mask layer pattern formed over the gate electrode pattern, wherein the gate electrode pattern surrounds the silicon layer pattern thereby filling up the under-cut space.

### BRIEF DESCRIPTION OF THE DRAWINGS

FIG. 1 is a simplified layout of a semiconductor device according to an embodiment of the present invention.

FIGS. 2a through 2h are simplified cross-sectional views illustrating a method for fabricating a semiconductor device according to an embodiment of the present invention.

### DESCRIPTION OF EMBODIMENTS

The present invention relates to a method for fabricating semiconductor devices having a surrounded channel transistor with a SOI semiconductor substrate. The surrounded channel transistor has a surrounded channel structure including an under-cut space and a gate structure that surrounds the surrounded channel structure, thereby improving the gate controllability of the device. Accordingly, a semiconductor device with a low voltage and high speed operation can be realized.

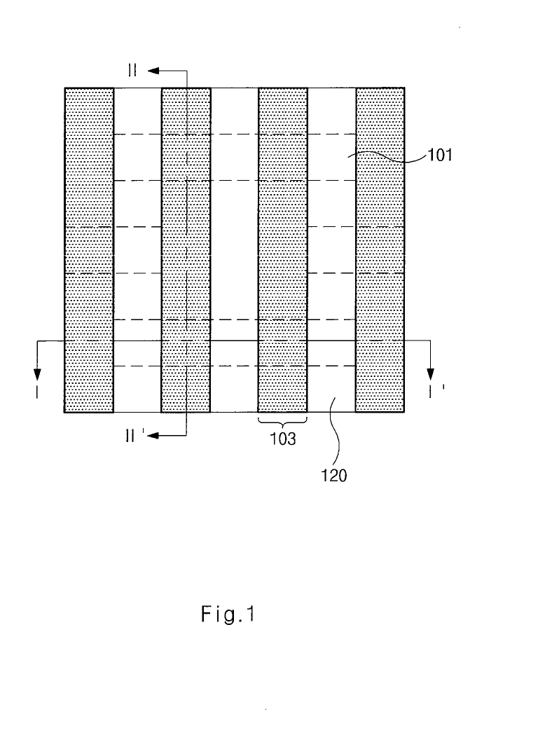

FIG. 1 illustrates a simplified layout of a semiconductor device according to an embodiment of the present invention. The semiconductor device includes an active region 101 defined by a device isolation structure 120 and a gate region 103.

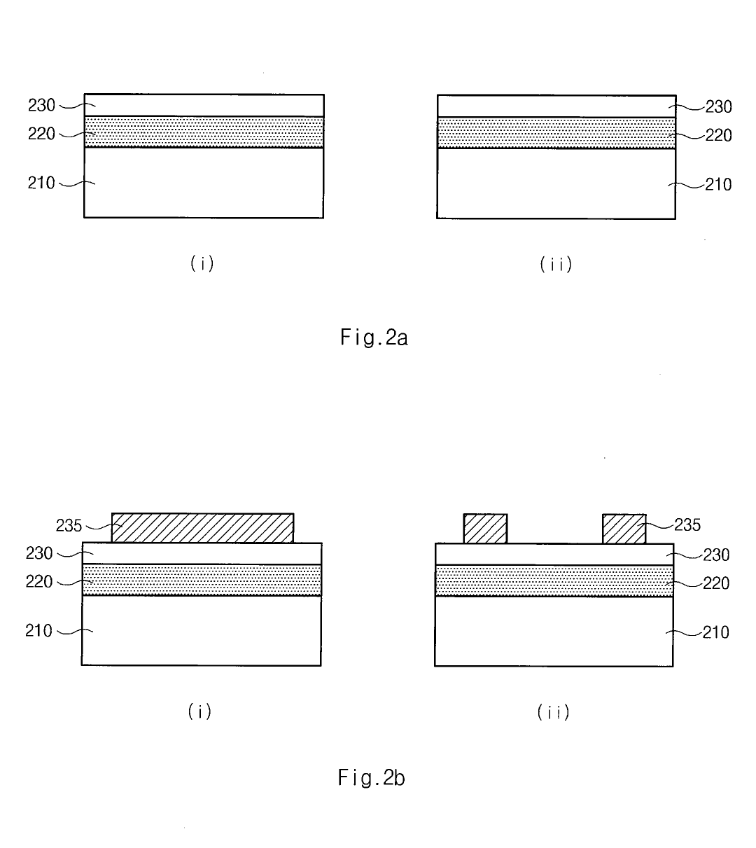

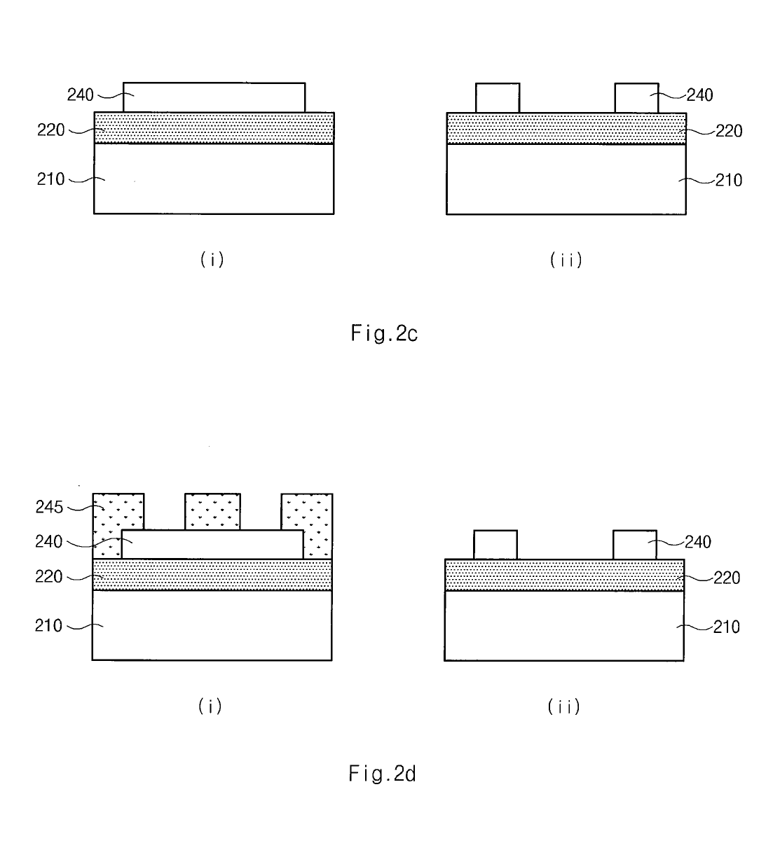

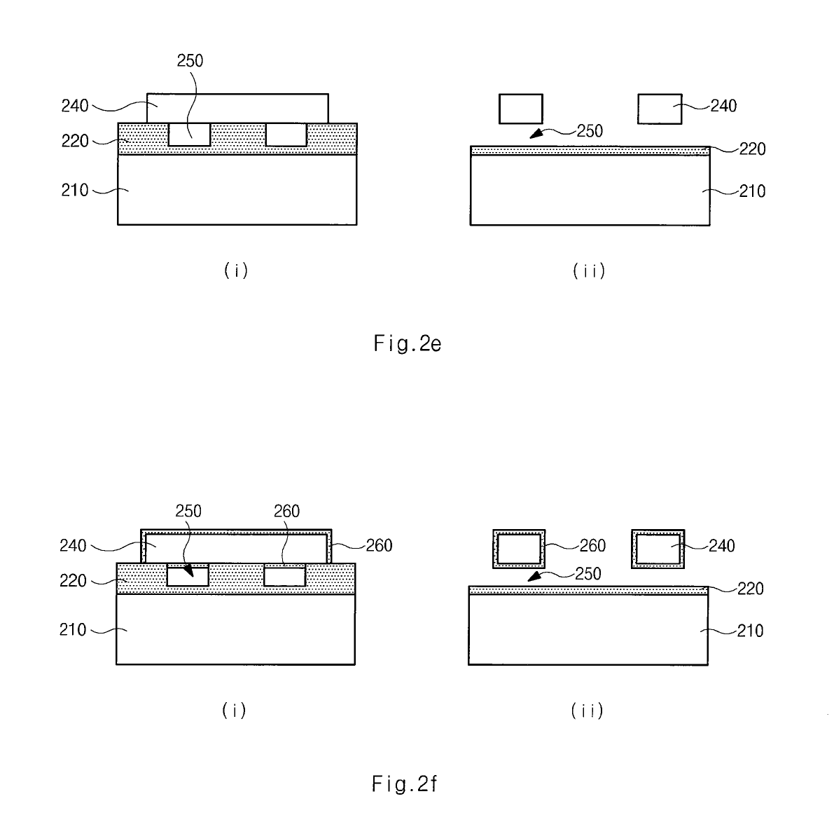

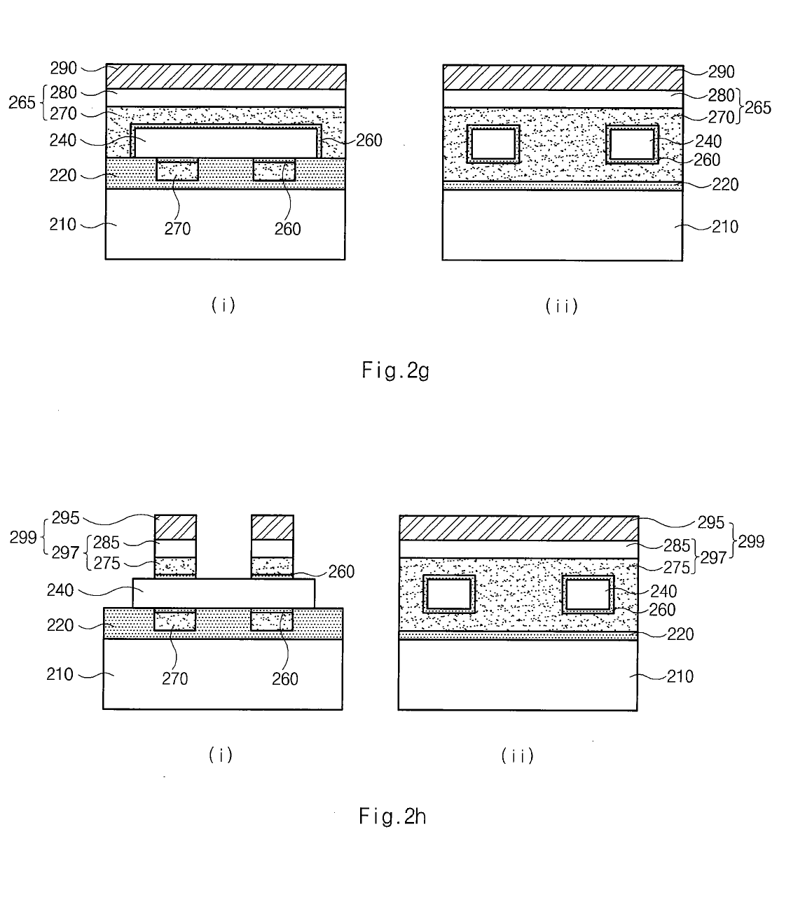

FIGS. 2a to 2h illustrate a method for fabricating a semiconductor device according to an embodiment of the present invention. Here, FIGS. 2a(i) through 2h(i) are cross-sectional views taken along a latitudinal direction in accordance with the line I-I′ of FIG. 1 and FIGS. 2a(ii) through 2h(i) are cross-sectional views taken along a longitudinal direction in accordance with the line II-II′ of FIG. 1.

Referring to FIGS. 2a to 2c, a photoresist film (not shown) is formed over a Silicon-on-Insulator (“SOI”) semiconductor substrate including a stacked structure of a first silicon layer 210, an insulating film 220, and a second silicon layer 230. The photoresist film is exposed and developed using a device isolation mask (not shown) to form a photoresist film pattern 235 defining the active region 101 shown in FIG. 1. The second silicon layer 230 is etched using the photoresist film pattern 230 as an etching mask to form a silicon layer pattern 240. The photoresist film pattern 230 is removed. In one embodiment of the present invention, the insulating film 220 is formed of a silicon oxide (SiO₂) film with its thickness in the range of about 2,000 Å to about 3,000 Å. In addition, a thickness of the second silicon layer 230 ranges from about 800 Å to about 1,000 Å in order to obtain a substantial channel length.

Referring to FIGS. 2d to 2f, a photoresist film (not shown) is formed over an entire surface of the resultant (i.e. over the silicon layer pattern 240 and the insulating film 220). The photoresist film is exposed and developed using a gate mask (not shown) to form a photoresist film pattern 245 defining the gate region 103 shown in FIG. 1. The insulating film 220 exposed by the photoresist film pattern 245 and the insulating film 220 under the silicon layer pattern 240 are selectively etched to form an under-cut space 250 where the insulating film 220 under the silicon layer pattern 240 is removed. The photoresist film pattern 245 is removed to expose the silicon layer pattern 240. A gate insulating film 260 is formed over the exposed silicon layer pattern 240. In one embodiment of the present invention, the selective etching process for the insulating film 220 is performed by an isotropic wet etching method using a HF solution with a substantial etching selectivity. In addition, a height of the under-cut space 250 ranges from about 800 Å to about 1,000 Å in a vertical direction. In another embodiment, the gate insulating film 260 is selected from the group consisting of a silicon oxide film, a hafnium oxide film, an aluminum oxide film, a zirconium oxide film, a silicon nitride film, or combinations thereof.

Referring to FIGS. 2g and 2h, a gate conductive layer 265 is formed over an entire surface of the resultant (i.e. over the insulating film 220 and the gate insulating film 260) to fill up the silicon layer pattern 240 and the underlying under-cut space 250. A gate hard mask layer 290 is formed over the gate conductive layer 265. The gate hard mask layer 290 and the gate conductive layer 265 are patterned using the gate mask to form a gate structure 299 including a stacked structure of a gate hard mask layer pattern 295 and a gate electrode 297 including a staked structure of a lower gate electrode 275 and an upper gate electrode 285. Here, the lower gate electrode 275 fills up the under-cut space 250 shown in FIG. 2f to surround the silicon layer pattern 240. In one embodiment of the present invention, the gate conductive layer 265 includes a stacked structure of a lower gate conductive layer 270 and an upper gate conductive layer 280. In addition, the lower gate conductive layer 270 is formed of a polysilicon layer. The upper gate conductive layer 280 is selected from the group consisting of a titanium (Ti) layer, a titanium nitride (TiN) film, a tungsten (W) layer, an aluminum (Al) layer, a copper (Cu) layer, a tungsten silicide (WSiₓ) layer, or combinations thereof. In another embodiment, the gate hard mask layer is formed of a nitride film.

As described above, the method for fabricating a semiconductor device in accordance with an embodiment of the present invention provides a surrounded channel transistor with a SOI semiconductor substrate, thereby improving gate controllability and operative capability. Accordingly, a semiconductor device with a low voltage and high speed operation can be realized.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or in a non volatile memory device. Other additions, subtractions, or modifications are obvious in view of the present disclosure and are intended to fall within the scope of the appended claims.

What is claimed is:

1. A method for fabricating a semiconductor device, the method comprising:
forming a silicon layer pattern in a Silicon-on-Insulator (“SOI”) semiconductor substrate to define an active region, the SOI semiconductor substrate having an insulating film;
selectively patterning the insulating film in the SOI semiconductor substrate by using a gate mask to form an under-cut space under the silicon layer pattern; and
forming a gate structure including a gate electrode pattern and a gate hard mask layer pattern formed over the silicon layer pattern, wherein the gate electrode pattern surrounds the silicon layer pattern to fill the under-cut space.

2. The method according to claim 1, wherein the SOI semiconductor substrate includes a stacked structure of a first silicon layer, the insulating film, and a second silicon layer.

3. The method according to claim 2, wherein forming the silicon layer pattern includes:
providing the SOI semiconductor substrate;
forming a photoresist film over the second silicon layer;
exposing and developing the photoresist film by using a device isolation mask to form a photoresist film pattern defining the active region;
etching the second silicon layer by using the photoresist film pattern as an etching mask to form the silicon layer pattern; and
removing the photoresist film pattern.

4. The method according to claim 1, wherein a thickness of the silicon layer pattern ranges from about 800 Å to about 1,000 Å.

5. The method according to claim 1, wherein the insulating film is formed of a silicon oxide (SiO₂) film in the thickness of about 2,000 Å to about 3,000 Å.

6. The method according to claim 1, wherein selectively etching the insulating film includes:
forming a photoresist film over the silicon layer pattern and the insulating film;
exposing and developing the photoresist film by using a gate mask to form a photoresist film pattern defining a gate region;
selectively etching out the insulating film exposed by the photoresist film pattern and the insulating film under the silicon layer pattern to form the under-cut space under the silicon layer pattern; and
removing the photoresist film pattern.

7. The method according to claim 1, wherein selectively etching the insulating film is performed by an isotropic wet etching method.

8. The method according to claim 7, wherein the isotropic wet etching method is performed using a HF solution.

9. The method according to claim 1, wherein a height of the under-cut space ranges from about 800 Å to about 1,000 Å in a vertical direction.

10. The method according to claim 1, wherein forming the gate structure includes:
forming a gate conductive layer over an entire surface of the resultant including the silicon layer pattern and filling up the under-cut space;
forming a gate hard mask layer over the gate conductive layer; and
pattering the gate hard mask layer and the gate conductive layer by using the gate mask to form the gate structure including a stacked structure of the gate hard mask layer pattern and the gate electrode, wherein the gate electrode surrounds the silicon layer pattern to fill the under-cut space.

11. The method according to claim 10, wherein the gate conductive layer includes a stacked structure of a lower gate conductive layer and an upper gate conductive layer.

12. The method according to claim 11, wherein the lower gate conductive layer is formed of a polysilicon layer.

13. The method according to claim 11, wherein the upper gate conductive layer selected from the group consisting of a titanium (Ti) layer, a titanium nitride (TiN) film, a tungsten (W) layer, an aluminum (Al) layer, a copper (Cu) layer, a tungsten silicide (WSiₓ) layer, and combinations thereof.

14. The method according to claim 1, further comprising forming a gate insulating film at the interface between the silicon layer pattern and the gate structure.

15. The method according to claim 14, wherein the gate insulating film is selected from the group consisting of a silicon oxide film, a hafnium oxide film, an aluminum oxide film, a zirconium oxide film, a silicon nitride film, and combinations thereof.
